(19) United States
(12) Patent Application Publication
(10) Pub. No.: US 2009/0027072 A1
(43) Pub. Date: Jan. 29, 2009

(54) APPARATUS FOR TESTING CHIPS WITH BALL GRID ARRAY

(75) Inventors: YONG-HUI FENG, Shenzhen (CN); I-HSIEN CHIANG, Tayuan, Taoyuan (TW); CHIH-YI TU, Tayuan (TW)

Correspondence Address: PCE INDUSTRY, INC.;ATT. CHENG-JU CHIANG, 458 E. LAMBERT ROAD, FULLERTON, CA, 92835, US

(73) Assignees: FUKUI PRECISION COMPONENT (SHENZHEN) CO., LTD., Shenzhen City (CN); FOXCONN ADVANCED TECHNOLOGY INC., Tayuan (TW)

(21) Appl. No.: 12/013,372

(22) Filed: Jan. 11, 2008

(30) Foreign Application Priority Data
Jul. 25, 2007 (CN) 200710075318.6

(51) Int. Cl. G01R 31/26

(52) U.S. Cl. 324/755

(57) ABSTRACT

An exemplary an apparatus for testing chips with ball grid array comprised of a number of solder balls is provided. The apparatus includes a main printed circuit board, a supporting board and a testing device. The main printed circuit board has a edge connector. The supporting board defines a number of electrically conductive through holes arranged in an array corresponding to the ball grid array. One end of each of the electrically conductive through holes is configured for electrically connection to the main printed circuit board, the other end of the electrically through holes is configured for receiving and electrically connecting the corresponding solder ball of the ball grid array. The testing device has a socket connector for insertion of the edge connector therein. The testing device is configured for testing the chip.

### BACKGROUND

1. Technical Field

The present invention relates to chips testing, particularly to an apparatus for testing chips with ball grid array.

2. Description of Related Art

Ball Grid Array (BGA) package is a surface-mount package that utilizes an array of metal spheres or balls as the means of providing external electrical connection, as opposed to the pin-grid array (PGA) package which uses an array of leads. The balls are composed of solder, and are arranged on and attached to a bottom side of a chip in a grid manner. The chip with ball grid array may be connected to a printed circuit board either by wire-bonding or flip-chip connection. BGA package as a packaging solution for integrated circuits presents many advantages such as reduced package size, high connecting density, capable of repairing, and so on.

However, an array of solder balls attached on a chip may have some inferior quality such as pseudo soldering. If the chip with inferior solder balls is packaged on the printed circuit board to form a product, performance of electronic devices using such product may be affected. Therefore, currently, a chip testing step is often performed so as to ensure each of the chips packaged on the printed circuit board can work. In detail, the chips with ball grid array are firstly soldered on the printed circuit board to form the product. Then, the chips soldered on the printed circuit board are tested. The unworkable chips are removed and turn into a reworking process. Finally, the reworking chips are again soldered on the printed circuit board of the product. However, a mass of time and labor is consumed in such a process. In addition, repeatedly soldering the chips on the printed circuit board and removing the chips from the printed circuit board may cause damage to the printed circuit board.

What is needed, therefore, is an apparatus for testing chips with ball grid array so as to test chips with ball grid array before being packaged on the printed circuit board to form the product.

### SUMMARY

One present embodiment provides an apparatus for testing chips with ball grid array comprised of a number of solder balls. The apparatus includes a main printed circuit board, a supporting board and a testing device. The main printed circuit board has an edge connector. The supporting board defines a number of electrically conductive through holes arranged in an array corresponding to the ball grid array. One end of each of the electrically conductive through holes being configured for electrically connection to the main printed circuit board, the other end of the electrically through holes is configured for receiving and electrically connecting the corresponding solder ball of the ball grid array. The testing device has a socket connector for insertion of the edge connector therein. The testing device is configured for testing the chip.

### BRIEF DESCRIPTION OF THE DRAWINGS

Many aspects of the present embodiment can be better understood with reference to the following drawings. The components in the drawings are not necessarily drawn to scale, the emphasis instead being placed upon clearly illustrating the principles of the present embodiment. Moreover, in the drawings, like reference numerals designate corresponding parts throughout the several views.

FIG. 1 is a schematic, cross-sectional view of a chip with ball grid array according to a present embodiment.

FIG. 2 is a schematic view of an apparatus for testing chips with ball grid array according to the present embodiment.

FIG. 3 is a schematic, cross-sectional view of the apparatus in FIG. 2 as viewed along line III-III.

FIG. 4 is a schematic view of the chip of FIG. 1 placed on the apparatus of FIG. 2 to perform a testing process.

FIG. 5 is a schematic, cross-sectional view of FIG. 4 as viewed along line IV-IV.

### DETAILED DESCRIPTION OF THE EMBODIMENTS

Embodiment will now be described in detail below with reference to the drawings.

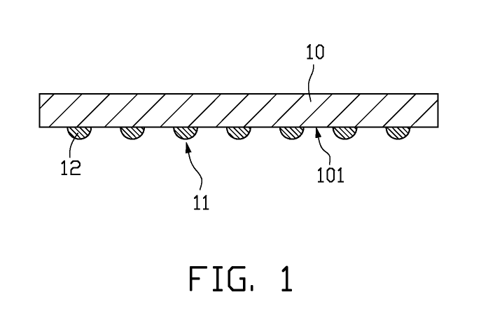

Referring to FIG. 1, an exemplary chip 10 is shown. The chip 10 can be a semiconductor integrated circuit chip. The chip 10 has a mounting surface 101. A number of solder balls 11 are arranged and attached on the mounting surface 101 in a grid array, thereby forming a ball grid array 11. The chip 10 can be packaged on a printed circuit board using a BGA packaging process.

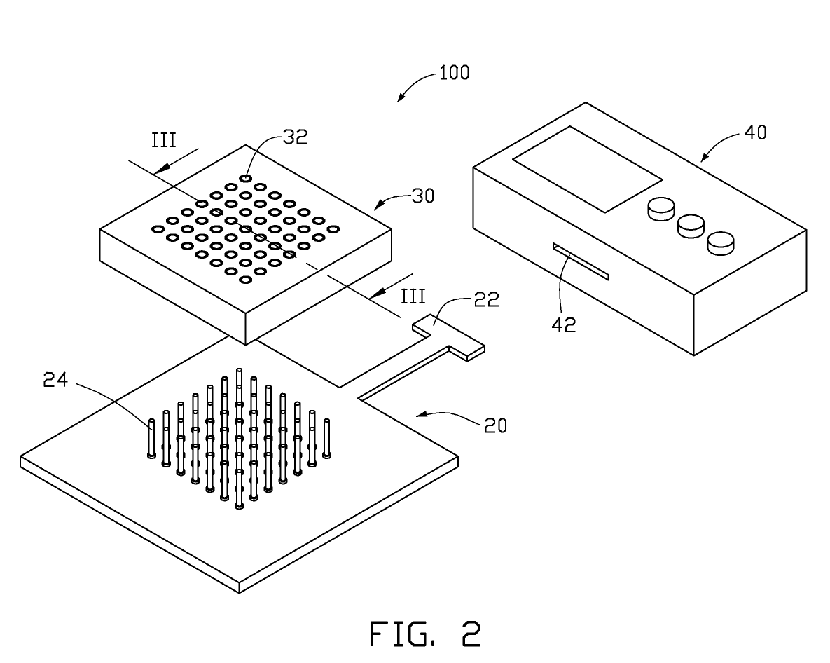

Referring to FIG. 2, an exemplary apparatus 100 for testing the chip 10 with the ball grid array 11 is shown. The apparatus 100 includes a main printed circuit board 20, a supporting board 30, and a testing device 40.

The main printed circuit board 20 has an edge connector 22. The edge connector 22 electrically connects to the main printed circuit board 20. The main printed circuit board 20 can be a flexible printed circuit board or a rigid printed circuit board, which has testing electrical traces (not shown) formed therein.

The main printed circuit board 20 has a number of electrically conductive poles 24 disposed thereon. Each of the electrically conductive poles 24 perpendicularly extends from the main printed circuit board 20. One end of the electrically conductive poles 24 electrically connects to the testing electrical traces of the main printed circuit board 20, and the other end of the electrically conductive poles 24 is configured for electrically connecting to the supporting board 30. The electrically conductive poles 24 are arranged in an array corresponding to the ball grid array 11 on the chip 10. That is to say, each of the electrically conductive poles 24 corresponds to one solder ball 11 of the ball grid array 11. Advantageously, each of the electrically conductive poles 24 can have a cylindrical configuration.

The edge connector 22 extends from an edge of the main printed circuit board 20 and has connecting electrical traces (not shown) connecting to the testing electrical traces of the main printed circuit board 20. The edge connector 22 is configured for connecting the main printed circuit board 20 to the testing device 40.

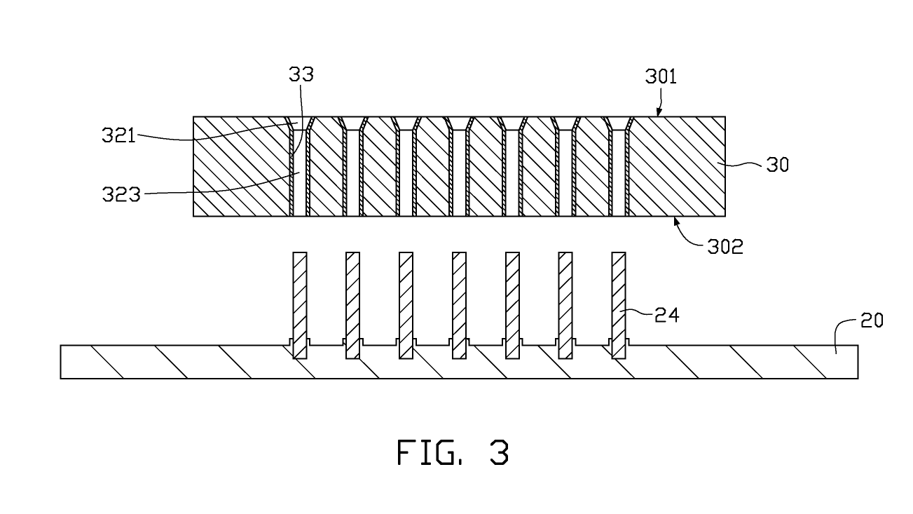

Referring to FIGS. 2 and 3, the supporting board 30 has a supporting surface 301 and a bottom surface 302 on two opposite sides of the supporting board 30. The supporting board 30 defines a number of electrically conductive through holes 32. Each of the electrically conductive through holes 32 penetrates the supporting board 30. That is, each of the electrically conductive through holes 32 is located between the supporting surface 301 and the bottom surface 302. The electrically conductive through holes 32 are arranged in an array corresponding to the ball grid array 11 on the chip 10, and also corresponding to the arrangement of the electrically conductive poles 24 on the main printed circuit board 20. Each of the electrically conductive through holes 32 has an electrically conductive layer 33 coated or deposited on a sidewall surface thereof.

Referring to FIG. 3, more preferably, each of the electrically conductive through holes 32 includes a first portion 321 and a second portion 323 communicating with each other. The first portion 321 is adjacent to the supporting surface 301. The first portion 321 is configured for receiving the corresponding solder ball 11 of the ball grid array 11 on the chip 10. A configuration of the first portion 321 mates with that of the corresponding solder ball 12 of the ball grid array 11. Because each of the solder balls 11 of the ball grid array 11 has a ball-shaped configuration, the first portion 321 can have either a semi-spherical shaped or a cone-shaped configuration mating with the ball-shaped solder ball 11. The first portion 321 has a configuration mating with the corresponding solder ball 12 so as to improve a contacting surface area and an electrical connection consistency therebetween. In the present embodiment, the first portion 321 has a configuration of cone-shaped. A diameter of the first potion 301 is progressively reduced in a direction away from the supporting surface 301.

The second portion 323 is adjacent to the bottom surface 302. The second portion 323 is configured for receiving the corresponding electrically conductive pole 24 on the main printed circuit board 20. The second portion 323 has a configuration mating with a configuration of the corresponding electrically conductive pole 24. Advantageously, in the present embodiment, the second portion 323 can have a cylindrical configuration mating with the cylindrical electrically conductive pole 24.

Referring to FIG. 2, the testing device 40 has a socket connector 42 configured for insertion of the edge connector 22 therein, thereby electrically coupling to the edge connector 22 of the main printed circuit board 20. Thus, the main printed circuit board 20 can connect to the testing device 40 via cooperation of the edge connector 22 and the socket connector 42. When the main printed circuit board 20 that is assembled with the supporting board 30 and the chip 10 is connected to the testing device 40, the testing device 40 can test the chip 10 so as to evaluate whether the chip 10 can work normally. The testing device 40 can be a testing machine on sale, for example, an In-Circuit Test (ICT) machine or the like. ICT machine can check short circuits, open circuits, resistance, capacitance, and other basic quantities of a populated printed circuit board, which will show whether the assembly was correctly fabricated.

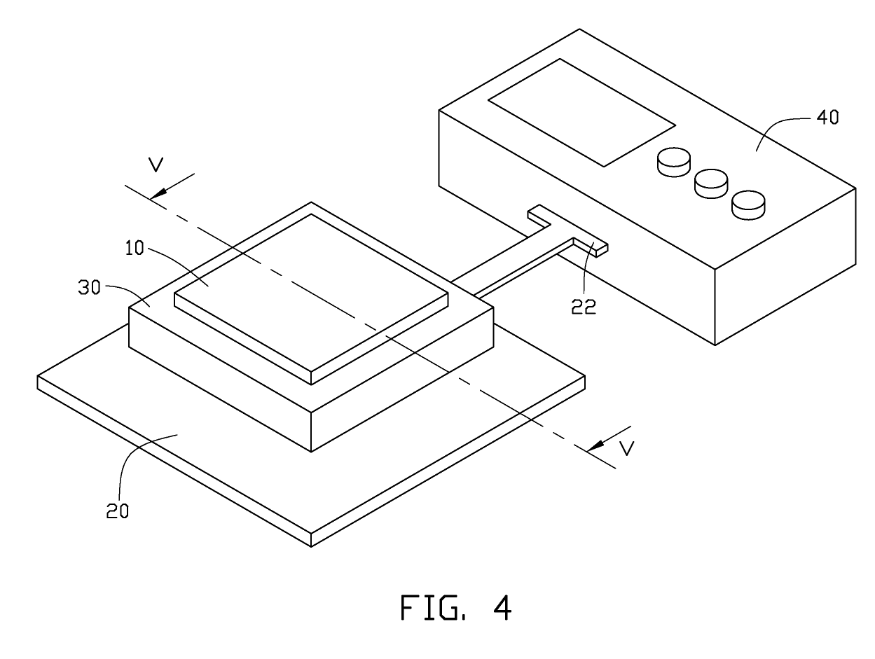

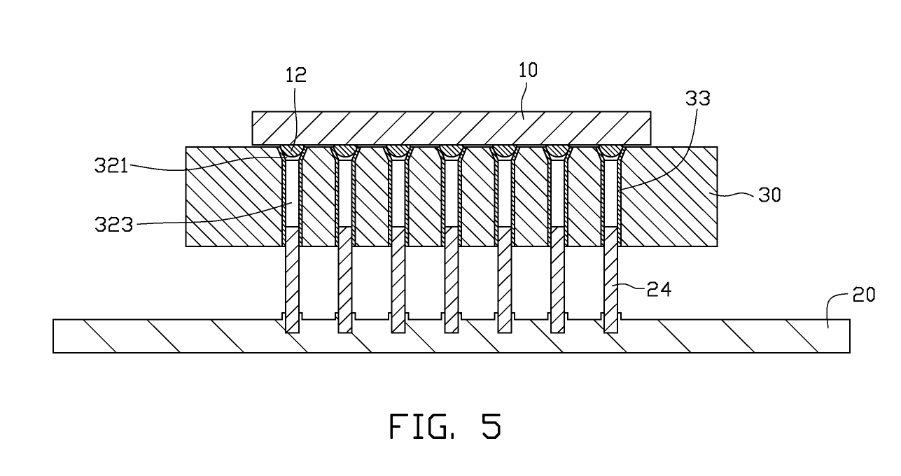

Referring to FIGS. 4 and 5, the chip 10 is placed on the supporting board 30 of the apparatus 100 for a test. Before testing, the supporting board 30 is assembled with the main printed circuit board 20. Each of the electrically conductive poles 24 is interposed into the corresponding second portion 323 of the electrically conductive through hole 32. Thus the electrically conductive poles 24 can electrically contact with the electrically conductive layer 33 formed on the sidewall surface of the second portion 323. Then, the chip 10 is attached onto the supporting board 30. Each of the solder balls 12 on the chip 10 is received in the corresponding first portion 321 of the electrically conductive through hole 32. Thus the solder ball 11 can electrically connect with the electrically conductive layer 33 formed on the surface of the first portion 321. As such, one end of each of the electrically conductive through holes 32 electrically connects to the main printed circuit board 20 via the electrically conductive poles 24, the other end of the electrically through holes 32 electrically connects the chip 10 via the corresponding solder balls 11 of the ball grid array 11. That is to say, the chip 10 electrically connects to the main printed circuit board 20 via the supporting board 30. Finally, the main printed circuit board 20 connects to the testing device 40 via cooperation of the edge connector 22 and the socket connector 42. Thus, the testing device 40 can test the chip 10.

If the chip 10 has nothing wrong and can work normally, the chip 10 can be removed from the supporting board 30 and go into a packaging process. If the chip 10 has some solder balls 12 with inferior quality such as pseudo soldering and cannot work normally, the chip 10 can be easily removed from the supporting board 30 and go into a repairing or reworking process. Because the chip 10 is removably placed on the supporting board 30 during the entire testing process and no soldering process is required, therefore damage to the chip 10 being tested can be avoided. In addition, the main printed circuit board 20 does not require to be soldered with the chip 10 during the entire testing process, therefore, damages to the main printed circuit board 20 are also eliminated, thereby improving a reliability of the test result.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. An apparatus for testing a chip with a ball grid array comprised of a plurality of solder balls, comprising:
a main printed circuit board having an edge connector;
a supporting board defining a plurality of electrically conductive through holes arranged in an array corresponding to the ball grid array, one end of each of the electrically conductive through holes being configured for electrically connection to the main printed circuit board, the other end of the electrically through holes being configured for receiving and electrically connecting the corresponding solder ball of the ball grid array; and
a testing device comprising a socket connector for insertion of the edge connector therein, the testing device being configured for testing the chip.

2. The apparatus as claimed in claim 1, wherein the main printed circuit board comprises a plurality of electrically conductive poles arranged in an array corresponding to the ball grid array, one end of the electrically conductive poles being electrically coupled to the main printed circuit board, the other end of the electrically conductive poles being configured for insertion into and electrically connection to the corresponding electrically conductive through hole.

3. The apparatus as claimed in claim 2, wherein each of the electrically through holes comprises a first portion and a second portion communicating with each other, the first portion being configured for receiving the corresponding solder ball, the second portion being configured for receiving the corresponding electrically conductive pole.

4. The apparatus as claimed in claim 3, wherein the first portion has either a semi-spherical configuration.

5. The apparatus as claimed in claim 3, wherein the first portion has a cone-shaped configuration.

6. The apparatus as claimed in claim 5, wherein the supporting board has a supporting surface and a bottom surface on two opposite sides of the supporting board, the first portion is adjacent to the supporting surface, a diameter of the first portion is progressively reduced in a direction away from the supporting surface.

7. The apparatus as claimed in claim 6, wherein the electrically conductive pole has a configuration of cylinder.

8. The apparatus as claimed in claim 7, wherein the second portion of the electrically conductive through hole has a configuration of cylinder.

9. The apparatus as claimed in claim 1, wherein each of the electrically conductive through holes has an electrically conductive layer formed on a sidewall surface thereof.

10. The apparatus as claimed in claim 1, wherein the main printed circuit board is either a flexible printed circuit board or a rigid printed circuit board.
